(19) United States
(12) Patent Application Publication
(10) Pub. No.: US 2014/0332747 A1
(43) Pub. Date: Nov. 13, 2014

(54) MEMRISTOR BASED ON A MIXED METAL OXIDE

(71) Applicants: Federal State Budgetary Institution &laquo;Federal Agency for Legal Protection of Military, Special, (unknown); and Dual Use Intelleuctual Activity Results&raquo; (FSBI &laquo;FALPIAR&raquo;), Moscow (RU); Moscow Institute of Physics and Technology (State University) Moscow Institute of Physics and, (unknown); Technology) (MIPT), Moscow (RU)

(72) Inventors: Anatoly Pavlovich Alekhin, Moscow (RU); Andrey Sergeevich Baturin, Dolgoprudny (RU); Irina Pavlovna Grigal, Sergiyev Posad (RU); Svetlana Aleksandrovna Gudkova, Dolgoprudny (RU); Andrey Mikhailovich Markeev, Moscow (RU); Anastasiya Aleksandrovna Chuprik, Moscow (RU)

(21) Appl. No.: 14/358,048

(22) PCT Filed: Nov. 2, 2012
(86) PCT No.: PCT/RU2012/000899

§ 371 Date: May 14, 2014

(30) Foreign Application Priority Data
Nov. 14, 2011 (RU) 2011146089

(51) Int. Cl. H01L 45/00

(52) U.S. Cl. CPC H01L 45/145; H01L 45/085
USPC 257/2

(57) ABSTRACT

The present invention relates to micro- and nano-electronics devices based on non-conventional materials. Such memristor devices with stable and reproducible characteristics can be used in the production of computer systems based on the analog architecture of artificial neural networks. The device in question consists of an active layer situated between two current conducting layers with which it is in electrical contact, said active layer being an ABOx-type oxide, where element B is titanium or zirconium or hafuium, and element A is a trivalent metal with an ion radius equal to 0.7-1.2 of the ion radius of titanium or zirconium or hafuium. If element B is titanium, then element A is selected from aluminium or scandium; if element B is zirconium or hafuium, then element A is selected from scandium or yttrium or luteciurn. The technical result of the proposed invention is an increase in the stability and reproducibility of the switching voltage and of the resistance in low and high impedance states.

The present invention relates to micro- and nano-electronics devices based on perspective materials and can be used in the production of computer systems based on memristor devices with stable and reproducible characteristics.

The use of the analog architecture of artificial neural networks opens new prospects for the production of computer systems which allow to optimize the principle of command processing as compared with the digital principle used universally in the classical von neumann computer.

At the heart of the proposed neuromorphic systems are memristors—bipolar devices, whose electrical resistance varies in proportion to a charge flowing through them. The memristor electrical characteristics are determined by the history of its operation, that is similar to the properties of the synapse of biological neural systems. The concept of memristor (resistor+memory, memristor), the fourth passive element of electrical circuits, was firstly introduced in 1971 [L. O. Chua, IEEE Trans. Circuit Theory 1971, 18, p. 507]. Up to 2008 the memristor systems were used only as mathematical abstractions for the simulation of signal processing, behavior of nonlinear semiconductor systems, electrochemical processes, and the simulation of human brain neurons. However, in practice the memristive effect was not demonstrated, as the change in electrical resistance for microscopic structures was negligible. When the opportunity arose to build up nanoscale structures, the Hewlett-Packard's workers for the first time demonstrated experimentally that the memristive effect can occur in the nanoscale metal-dielectric-metal structures due to the flow of charges in an ultra-fine dielectric layer upon application of electric field, for example, when oxygen vacancies move in the layer of titanium dioxide TiO₂ of about 5 nm thickness [D B Strukov, G. S. Snider, D. R. Stewart, R. S. Williams. The missing memristor found. Nature 2008 , 453 , p. 80; Williams R. S., Yang J., Pickett M., Ribeiro G., Strachan J. P. Memristors based on mixed-metal-valence compounds. WO2011028208. 10.03.2011]. In recent years, the resistive switching mechanism in the layers of titanium oxides with symmetric Pt electrodes has been studied comprehensively [J. J. Yang et al. Memristive switching mechanism for metal/oxide/metal nanodevices. Nature Nanotechnology 2008, 3, p. 429; J. P. Strachan, J. J. Yang et al. Nanotechnology 2009, 20, p. 485701].

For the most types of memristors, including the memristors based on transition metal oxides, the sufficiently high instability and non-reproducibility of values for the parameters, such as switching voltage, resistance in low-impedance and high-impedance states, still remain an open question [S. H. Jo, T. Chang, I. Ebong et al. Nanoscale Memristor Device as Synapse in Neuromorphic Systems. Nano Lett. 2010, 10, p. 1297; Q. Xia, J. J. Yang, Wei Wu et al. Self-Aligned Memristor Cross-Point Arrays Fabricated with One Nanoimprint Lithography Step. Nano Lett. 2010, 10, p. 2909]. This problem is often solved by the running time of each memristor cell [Q. Xia, J. J. Yang, Wei Wu et al. Self-Aligned Memristor Cross-Point Arrays Fabricated with One Nanoimprint Lithography Step. Nano Lett. 2010 , 10 , p. 2909 ], however this procedure does not guarantee the long-term stability of memristor characteristics, especially with regard to the special features of the analog architecture of neuromorphic systems, when a discrete cell can be referred to after sufficiently long intervals of time.

The dominant cause for the instability of memristor characteristics is a nonuniform distribution of electric field in the memristor active layer due to the non-ideal geometry of the memristor cell or the non-ideal active layer. Accordingly, there exist two ways to improve the stability of memristor characteristics: to improve geometry, as well as to search for new materials and new methods for forming the memristor active layer and electrodes. Ideally, both approaches should be used in parallel, but the second approach is primary, since it allows for improving the basic cell of memristor.

As mentioned above, the memristive effect was firstly demonstrated in 2008 for the Pt—Ti02—Tiₙ02ₙ—i—Pt system [D. B. Strukov, G. S. Snider, D. R. Stewart, R. S. Williams. The missing memristor found. Nature 2008, 453, p. 80]. In recent years, a variety of alternative materials has been proposed for use as the memristor active layer. The memristive effect has been demonstrated in the nanopore-ion solution system [ M. Krems, Y. V. Pershin, M. Di Ventra. Nano Lett. 2010, 10, p. 2674 ], in the devices based on conductive polymers [T. Berzina, S. Erokhina, P. Camorani et al. Applied materials & interfaces 2009, 1, p. 2115 ], and on the protein molecules [Dianzhong W. Manufacturing method for protein structure quick switch memristor array. CN101630662. 20.02.2010], and the nanoparticle assembles [Kim T. H., Cheon J. W., Jang J. -T. Nanoparticle assembly-based switching device. WO2010062127. 03.06.2010], in particular the monocrystal magnetite nanoparticles (Fe₃C>₄) [T. H. Kim, E. Y. Jang, N. J. Lee et al. Nano Lett. 2009, 9, p. 2229]. However, the memristors based on such materials are formed by methods, which are indistinctive for the modern silicon technology for creating integrated circuits. Therefore, using these materials as the memristor active layer substantially hinders the memristor integration into the modern production.

To simplify the integration and to reduce the cost of production, a three-layer structure is used as the memristor active layer, which consists of successive layers of an n-type semiconductor, an intrinsic semiconductor and a p-type semiconductor of a few nanometers in thickness [Wen D., Bai X. Nanostructure quick-switch memristor and method of manufacturing the same. WO 2011000316 . 06.01.2011]. The relatively high speed of switching from the high-impedance state to the low-impedance state and vice versa (similar to PIN diodes) is an additional advantage of such memristor device. However, the characteristics of such memristors can be poorly reproducible. It is defined by the fact that with the use of nanoelectrodes the concentration and distribution of a dopant in doped semiconductor layers with a few nanometers in thickness can contribute greatly to the memristor cell resistance.

Despite a wide range of materials used as the memristor active layer, the metal-dielectric-metal nanostructures are still the most popular and promising. The structures of this kind, in contrast to the most of structures described above, are built by conventional methods used in the state-of-the art technology of silicon integrated circuits. Thus, the wide use of the metal-dielectric-metal nanostructures for creating the memristors is determined by convenience and efficiency of the potential integration of such memristor devices into modern production. Furthermore, the potentialities of metal oxides, in particular, transition metals, as applied to the memristor technologies, have not been fully studied yet.

Since in the traditional system of TiO₂—TiₙO₂ₙ₋₁ layers the distribution of charge carriers (oxygen vacancies) through the film thickness is of random nature, attention is focused on creating a tailored doping profile within the active layer volume for effective control of the memristor charge carriers [Quitoriano N. J., Kuekes P. J., Yang J. Controlled placement of dopants in memristor active regions. WO2010085225. 29.07.2010]. The similar results can be achieved by the ion implantation of elements with a large number of valence electrons into the active layer volume and by subsequent annealing [Tang D., Xiao N. Method for forming memristor material and electrode structure with memristance. US20090317958. 24.12.2009]. As this takes place, some regions rich in negatively charged vacancies are formed at a definite depth. However, the use of ion implantation allows to exactly controlling and flexibly adjusting the amount and the distribution of implanted atoms and, correspondingly, the regions rich in charge carriers in the films of thickness 10 nm or more. Since the memristor active layer often has a thickness of about 3 to 10 nm, the ion implantation method is not optimal for forming homogeneous distribution of dopants and, therefore, does not improve the stability of memristor characteristics.

Many promising oxides are offered for use as material for the memristor active layer [Williams R S, Yang J., Pickett M., Ribeiro G., Strachan J P Memristors based on mixed-metal-valence compounds. WO2011028208. 10.03.2011]:

TiO₂—TiₙO₂ₙ₋₁, where n=3 . . . 9,

ZrO₂—ZrO₂₋ₓ, where x=0.01 . . . 0.5,

HfO₂—HfO₂₋ₓ, where x=0.01 . . . 0.5,

TiₐZr_{b}Hf_{c}O₂—(Ti_{d}ZrₑHf_{f})nO₂ₙ₋₁, where a+b+c=1, d+e+f=1, n=3 . . . 15,

VO₂—VₙO₂ₙ₋₁, where n=3 . . . 9,

VₐNb_{b}Ta_{c}Oᵣ(VₐNbₑTa_{f})ₙO₂ₙ₋₁, where a+b+c=1, d+e+f=1, n=3 . . . 12,

Nb₂O₅—NbO₂,

Nb₂O₅—multicomponent oxide Nb (oxidation degree +5 or +4), including Nb₂O₅—NbO₂₊ₓ, where x=−0.5 . . . 0.5,

Ta₂O5—TaO₂,

Ta₂0₅- multicomponent oxide Ta (oxidation degree +5 or +4), including Ta₂O₅—TaO₂₊ₓ, where x=−0.5 . . . 0.5,

MoO₃—MoₙO₃ₙ₋₁, where n=4 . . . 12,

WO₃—WₙO₃ₙ₋₁, where n=4 . . . 12,

CrₐMo_{b}W_{c}O₃—(Cr_{d}Mo_{c}W_{f})ₙO₃ₙ₋₁, where a+b+c=1, d+e+f=1, n=4 . . . 15,

Fe₂O3—Fe₃O₄,

Ni₂O₃—Ni₃O₄,

CO₂O₃—Co₃O₄.

The presented extensive list of oxides does not consider a wide class of ABOₓ-type mixed oxides, where A is a divalent or trivalent element, while B is titanium or zirconium or hafnium. Oxides of this type have a wide range of physical and structural properties, that allows to flexibly control the concentration of the charge carriers, the value of conductivity, the degree of memristor active layer homogeneity and, consequently, to improve the stability of memristor characteristics.

The most technically close device admitted as prior art is the memristor based on the A⁺⁴B⁴⁺0³⁻—type mixed oxide, where A is a divalent element, and B is titanium or zirconium or hafnium [Quitoriano N. J., Ohlberg D.; Kuekes P. J., Yang J. Using alloy electrodes to dope memristors. W02010085226. 29.07.2010].

Since the ionic radii of atoms of titanium or zirconium or hafnium and Group II metals differ greatly in size (except for a couple of Mg and Ti), the bonding enthalpy is positive, and the bonding energy is high enough. As a result, this memristor must have a relatively low homogeneity and conductivity, which in turn leads to non-uniformity of the electric field distribution in the active layer and, accordingly, poor stability and reproducibility of the memristor characteristics.

An object of this invention is to increase the stability and the reproducibility of the memristor characteristics (switching voltage, resistance in low-impedance and high-impedance states), whose resistance is changed when electric current is passed through them.

The object can be achieved by providing for the mixed metal oxide-based memristor, consisting of at least three alternating layers, namely an active layer situated between two conductive layers, and the active layer being a mixed oxide, the first element of which is titanium or zirconium or hafnium, the second element is a metal according to the invention, being a trivalent metal with the ionic radius equal to 0.7-1.2 of the ionic radius of titanium or zirconium or hafnium, respectively, wherein the ratio of the mixed oxide ingredients is as follows, at. %: the first element 60-99, the second element 40-1.

Moreover, if the mixed metal oxide comprises titanium as the first element, aluminum or scandium is used as the second element. If the mixed metal oxide comprises zirconium or hafnium as the first element, scandium or yttrium or lutetium is used as the second element.

The following drawings illustrate the proposed device:

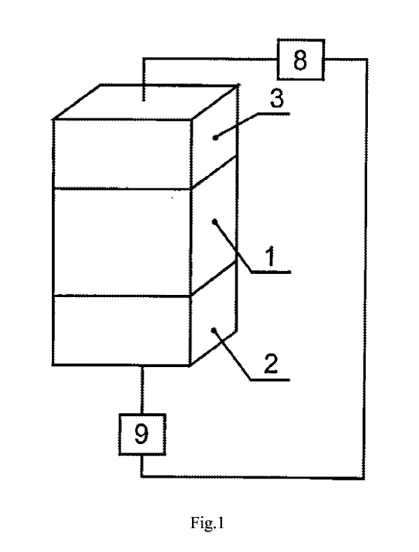

FIG. 1. Memristor diagram; and

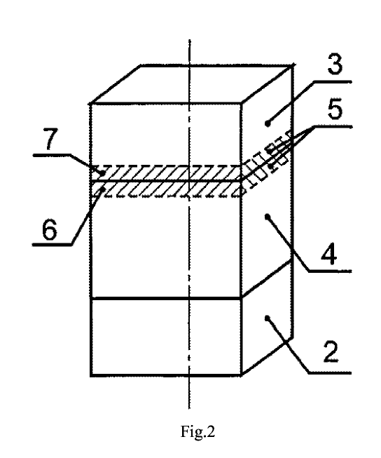

FIG. 2. Primary and secondary sublayers of the memristor active layer.

The mixed metal oxide-based memristor comprises an active layer 1 situated between a bottom conductive electrode 2 and a top conductive electrode 3. The active layer 1 consists of a primary active sublayer 4 and a secondary active sublayer 5. The secondary active sublayer 5 comprises an adjacent boundary region 6 of the active layer 1 and a boundary region 7 of the electrode 3. A voltage source 8 is connected to the electrodes 2 and 3. Furthermore, a current meter 9 is connected into the circuit.

The active layer 1 is a ABOₓ-type mixed oxide, wherein the element B is titanium or zirconium or hafnium, while the element A is a trivalent metal with an ionic radius close in magnitude to the ionic radius of the element B. In this case if the element B is titanium, then aluminum or scandium must be selected for the element A. If the element B is zirconium or hafnium, the element A must be scandium or yttrium or lutetium.

The active layer 1 is a material capable of transporting the charge. The charge carriers in the active layer of mixed oxide are oxygen vacancies. Depending on the chemical composition and structure of the electrodes, application of electric field of a certain magnitude or polarity between the electrodes using the voltage source 8 leads to at least one of the following effects: 1) diffusion of oxygen atoms through the electrode 3 and their concentration at an interface of the electrode 3 and the active layer 1; 2) oxidation (or recovery) of the boundary region 7 of the electrode 3 in contact with the active layer 1, and accordingly, to an excess (or deficit) of oxygen vacancies near the top electrode-active layer interface or the bottom electrode-active layer interface. Thus, the application of electric field changes the concentration of charge carriers in the active layer and the distribution of carrier carriers across the active layer thickness. The active layer resistance is changed, and changes are recorded by the current meter 9.

Thus, the active layer 1 can be functionally divided into two sublayers: the primary active sublayer 4 and secondary active sublayer 5. The primary active sublayer 4 is a semiconductor or a dielectric material nominally. Thereby, the primary active sublayer 4 is capable of transferring ions, which in this case plays a role similar to the impurity atoms and are the charge carriers, i.e. actually the primary active sublayer 4 is a conductor with the low ionic conductivity. This property of the primary active sublayer 4 is required for controlling the flow of charge carriers through the memristor. The secondary active sublayer 5 is a source of the charge carriers for the primary active sublayer 4. With the mixed metal oxide-based memristor, the secondary active sublayer 5 is a set of the boundary region 7 of the electrode 3, exposed to oxidation and recovery upon application of voltage, and the adjacent boundary region 6 of the active layer 1, which is enriched and depleted in the oxygen vacancies during oxidation and recovery of the boundary region 7 of the electrode 3.

When electric field from the voltage source 8 is applied, the oxygen vacancies between the electrodes 2 and 3 in the active layer can drift along the vertical axis of the device to nanometer distances due to a bias of the boundary between the primary active sublayer 4 and the secondary active sublayer 5, that results in change of the memristor resistance.

Since the above mixed metal oxide is used as the active region material, and the ionic radii of the atoms of titanium or zirconium or hafnium and Group III metals differ little in size (the size of ionic radii of atoms of Group III metals is generally about 0.7-1.2 of the ionic radius of titanium or zirconium or hafnium), the bonding enthalpy is negative, and the bonding energy is quite small. In particular, the ratio of the magnitude of yttrium ionic radius (0.093 nm according to Table of ionic radii) to the magnitude of zirconium ionic radius (0.079 nm according to Table of ionic radii) is 1.18. Appropriately, the bonding enthalpy of zirconium and yttrium in the Y_{0.1}Zr_{0.9}Oₓ mixed oxide is negative and is of about −0.05 eV/cation, while the bonding energy is small and is of 0.03 eV/cation.

The active layer of the mixed metal oxide-based memristor with negative bonding enthalpy and low bonding energy must have high homogeneity and conductivity, that in turn must provide the high stable and reproducible characteristics of the mixed metal oxide-based memristor.

Examples of the claimed memristor implementation.

### Example 1

To implement a switching matrix of nine mixed metal oxide-based memristors, a substrate of size 1 cm×1 cm cut out from a silicon wafer was used. For electrical insulation of the substrate and the switching matrix, a SiO₂ oxide of 100 nm thick was formed on the substrate by thermal oxidation at 1000° C. at room conditions. Next, using the method of electron-beam lithography, three bottom electrodes were formed in the center of substrate, which constituted a set of parallel nanowires made of palladium as rectangular strips having a width of 300 nm and a length of 50 microns. The distance between the nanowires was 5 μm. The thickness of palladium layers was 20 nm.

In a separate cycle of the electron-beam lithography three palladium contact pads of 100×100 μm² size and palladium wires of width 300 nm and 100 nm thick were made, which provided the electrical contact between the bottom electrodes and the palladium pads.

An active layer was deposited on the substrate with the formed bottom electrodes. For this purpose, the Al_{0.15}Ti_{0.85}Oₓ mixed oxide of thickness 20 nm was applied by the method of atomic layered deposition. The Al_{0.15}Ti_{0.85}Oₓ films were deposited at the substrate temperature of 300° C. with alternation of the reaction cycles: the first cycle Al(CH₃)₃—H₂O and twenty-four cycles Ti(OC₂H₅)₄—H₂O. The total number of cycles was five hundred.

To prevent full covering and electrical insulation of the contact pads of the bottom electrodes by the Al_{0.15}Ti_{0.85}Oₓ dielectric layer, prior to apply the dielectric layer, the sample surface was fully covered with polymethylmethacrylate electronic resist. In the center of the sample a square window of 25×25 μm size was opened using the electron-beam lithography, and then the mixed oxide was applied. Upon the resist removal, the dielectric layer remained only on the central portion of electrodes, while edge portions thereof were kept conductive.

Further, using the electron-beam lithography method, three top electrodes were formed, constituting a set of titanium nanowires parallel to each other and perpendicular to the bottom electrodes. The top electrodes had a width of 300 nm and a length of 50 μm, the distance between the nanowires was 5 μm. The thickness of titanium layers was 50 nm. The top electrodes were disposed on the sample so that they formed nine intersections with the bottom electrodes. In this case, the profile of palladium and titanium nanowires was rectangular in shape.

In a separate cycle of the electron-beam lithography three palladium contact pads of 100×100 μm² size and palladium wires of width 300 nm and 100 nm thick were made, which provided the electrical contact between the top electrodes and the palladium pads.

Using the standard method of copper etching in an aqueous solution of ferric chloride, a board with copper square contact pads of lateral size 3×3 mm² was fabricated from a foil-coated glass-fiber laminate of size 3×3 cm².

The electrical contact between the nanowires and contact pads on the board was provided by means of a gold wire of 25-μm diameter by thermo-compression welding.

By pairs between the top and bottom electrodes the meter Agilent U2722A was connected, comprising a power supply and a current meter. The standard control software for the meter was used for measuring current-voltage characteristics in the voltage range from 2.5 V to 2.5 V, as well as for switching the memristors from the high-impedance to low-impedance state and vice versa. Resistance of the memristor high-impedance and low-impedance states was averaged over 10³ cycles of switching from the high-impedance to the low-impedance state and vice versa.

The nine formed memristors based on the Al_{0.15}Ti_{0.85}Oₓ mixed oxide exhibited the following characteristics: switching voltage from the high-impedance to low-impedance state was 2,1±0,2 V. Resistance in the high-impedance state measured at voltage of 0.3 V was R_{OFF}=12200±500 Ohm, R_{ON}=930±50 Ohm. Maximum spread of the resistance values in the high-impedance sate and in the low-impedance state was within 5.5%, spread of the switching voltage values did not exceed 10%. These results show that the use of the Al_{0.15}Ti_{0.85}Oₓ mixed oxide as the active layer allows to create the memristor nanostructure with yje high-stable and well reproducible characteristics.

### Example 2

The second example of memristor implementation is technically similar to the first one. Distinction is as follows: 1) the switching matrix was formed of sixteen memristors; 2) the active layer was formed by the Y_{0.1}Zr_{0.9}Oₓ mixed oxide of 5 nm thick; 3) zirconium was deposited as the top electrode. The zirconium layer was of 2 nm thick and was in direct contact with the active layer. The zirconium layer was coated with palladium of 10 nm thick.

The sixteen formed memristors based on the Y_{0.1}Zr_{0.9}Oₓ mixed oxide exhibited the following characteristics: switching voltage from the high-impedance to the low-impedance state was 1.6±0.1 V. Resistance in the high-impedance state measured at voltage of 0.2 V was R_{OFF}=1450±70 Ohm, R_{ON}=110±7 Ohm. Spread of the resistance values in the high-impedance sate and in the low-impedance state was within 6%. The obtained result shows that the use of the Y_{0.1}Zr_{0.9}Oₓ mixed oxide as the active layer allows to create the memristor nanostructure with the high-stable and well reproducible characteristics.

### Example 3

The third example of memristor implementation is technically similar to the first one. Distinction is as follows: 1) the active layer was formed by the Lu_{0.45}Zr_{0.65}Oₓ mixed oxide of 6 nm thick; 2) zirconium was deposited as the top electrode. The zirconium layer was of 2 nm thick and was in direct contact with the active layer. The zirconium layer was coated with palladium of 10 nm thick.

The nine formed memristors based on the Lu_{0.45}Zr_{0.65}Oₓ mixed oxide exhibited the following characteristics: switching voltage from the high-impedance to the low-impedance state was 2.1±0.2 V. Resistance in the high-impedance state measured at voltage of 0.2 V was R_{OFF}=10150±600 Ohm, R_{ON}=6200±200 Ohm. Spread of the resistance values in the high-resistance in the low-resistance state and the switching voltage values was in the range of 6%. Spread of the switching voltage values did not exceed 10%. The obtained result shows that the use of the Lu_{0.45}Zr_{0.65}Oₓ mixed oxide as the active layer allows to create the memristor nanostructure with the high-stable and well reproducible characteristics.

Thus, the combination of known memristor features and distinguishing features makes it possible to obtain a new technical result, namely, enables to improve the stability and reproducibility of memristor characteristics, whose resistance alters when electric current is passed through them due to increase in the homogeneity and conductivity of the memristor active layer.

What is claimed is:

1. A mixed metal oxide-based memristor, comprising at least three alternating layers, namely an active layer situated between two conductive layers, said active layer being a mixed oxide, the first element of which is titanium or zirconium or hafnium, while the second element is a metal, wherein said metal is trivalent with an ionic radius equal to 0.7-1.2 of the ionic radius of titanium or zirconium or hafnium, and the ratio of the mixed oxide ingredients is as follows, at. %: the first element 60-99, the second element 40-1.

2. The memristor according to claim 1, wherein said mixed metal oxide comprises titanium as the first element and aluminum or scandium as the second element.

3. The memristor according to claim 1, wherein said mixed metal oxide comprises zirconium or hafnium as the first element, and scandium or yttrium or lutetium as the second element.
